(19) United States
(12) Patent Application Publication
(10) Pub. No.: US 2025/0081554 A1
(43) Pub. Date: Mar. 6, 2025

(54) SEMICONDUCTOR DEVICE

(71) Applicant: POWER MASTER SEMICONDUCTOR CO., LTD., Cheongju-si (KR)

(72) Inventors: Jeonghoon SEOL, Incheon (KR); Youngjae KIM, Incheon (KR)

(21) Appl. No.: 18/814,785

(22) Filed: Aug. 26, 2024

(30) Foreign Application Priority Data
Aug. 29, 2023 (KR) 10-2023-0113811

(51) Int. Cl. H01L 29/06; H01L 29/40; H01L 29/417; H01L 29/66; H01L 29/78

(52) U.S. Cl. CPC H10D 62/127; H10D 30/0297; H10D 30/668; H10D 64/01; H10D 64/117; H10D 64/252

(57) ABSTRACT

A semiconductor device is provided. In the semiconductor device, on the upper surface of the semiconductor device, a first horizontal virtual line, a second horizontal virtual line, a third horizontal virtual line, and a fourth horizontal virtual line which extend in parallel with one another along a first axial direction may be defined, and on the upper surface of the semiconductor device, a first vertical virtual line, a second vertical virtual line, and a third vertical virtual line which extend in parallel with one another along a second axial direction perpendicular to the first axial direction may be defined, and the semiconductor device may include a trench region, a gate contact region, and a source contact region, and the trench region may be formed so as to extend in the second axial direction along the first vertical virtual line, extend along the first axial direction from the intersection of the first vertical virtual line and the first horizontal virtual line, extend along the second axial direction from the intersection of the first horizontal virtual line and the second vertical virtual line, and extend along the first axial direction from the intersection of the second vertical virtual line and the second horizontal virtual line, and on the trench region, a plurality of gate polysilicon contact holes and a plurality of shielded polysilicon contact holes may be formed.

### CROSS-REFERENCE TO RELATED APPLICATION

This application claims priority to and the benefit of Korean Patent Application No. 10-2023-0113811 filed in the Korean Intellectual Property Office on Aug. 29, 2023, the entire contents of which are incorporated herein by reference.

### BACKGROUND

### (a) Field

The present disclosure relates to a semiconductor device.

### (b) Description of the Related Art

Since power MOSFETs (Metal Oxide Semiconductor Field Effect Transistors) are a type of metal-oxide-semiconductor field-effect Transistors, and have low driving voltages and high switching speeds, they are widely used in high-power applications such as inverters, power supply devices, and motor drives.

A power MOSFET to be disclosed is characterized by a trench structure, and a trench may be formed in a vertical direction in a silicon wafer such that when the device is turned on, current flows in the semiconductor. A general trench MOSFET is formed by forming a trench structure in a silicon epitaxial layer including n-doped and p-doped regions and forming a gate region inside the trench structure such that a channel is formed vertically along the side surfaces of the trench. By this vertical channel structure, it is possible to save the area that is occupied by the channel, and reduce the overall size of the device, as compared to the existing planar type. Also, by applying the trench technique, it is possible to remove junction field effect transistor (JFET) regions present in the existing planar type MOSFETs, thereby implementing lower impedance and less switching loss, and accordingly, it is possible to improve power efficiency and device performance.

### SUMMARY

The present disclosure attempts to provide a semiconductor device capable of forming electrode contact holes even when trench width is reduced in a trench MOSFET having two or more electrodes in one trench structure to improve the impedance.

In a semiconductor device according to an embodiment, on the upper surface of the semiconductor device, a first horizontal virtual line, a second horizontal virtual line, a third horizontal virtual line, and a fourth horizontal virtual line which extend in parallel with one another along a first axial direction may be defined, and on the upper surface of the semiconductor device, a first vertical virtual line, a second vertical virtual line, and a third vertical virtual line which extend in parallel with one another along a second axial direction perpendicular to the first axial direction may be defined, and the semiconductor device may include a trench region, a gate contact region, and a source contact region, and the trench region may be formed so as to extend in the second axial direction along the first vertical virtual line, extend along the first axial direction from the intersection of the first vertical virtual line and the first horizontal virtual line, extend along the second axial direction from the intersection of the first horizontal virtual line and the second vertical virtual line, and extend along the first axial direction from the intersection of the second vertical virtual line and the second horizontal virtual line, and on the trench region, a plurality of gate polysilicon contact holes and a plurality of shielded polysilicon contact holes may be formed.

In some embodiments, among the plurality of gate polysilicon contact holes, a first gate polysilicon contact hole may be formed so as to extend along the first axial direction between the intersection of the first vertical virtual line and the first horizontal virtual line and the intersection of the first horizontal virtual line and the second vertical virtual line.

In some embodiments, among the plurality of shielded polysilicon contact holes, a first shielded polysilicon contact hole may be formed so as to extend along the first axial direction between the intersection of the second vertical virtual line and the second horizontal virtual line and the intersection of the second horizontal virtual line and the third vertical virtual line.

In some embodiments, the semiconductor device may further include a first source contact hole that is formed so as to extend along the second axial direction between a portion of the trench region extending in the second axial direction along the first vertical virtual line and a portion extending in the second axial direction along the second vertical virtual line, and the semiconductor device may further include a second source contact hole that is formed so as to extend along the second axial direction between a portion of the trench region extending in the second axial direction along the second vertical virtual line and a portion extending in the second axial direction along the third vertical virtual line.

In some embodiments, the trench region may be formed so as to extend along the first axial direction from the intersection of the first vertical virtual line and the fourth horizontal virtual line, extend along the second axial direction from the intersection of the fourth horizontal virtual line and the second vertical virtual line, and extend along the first axial direction from the intersection of the second vertical virtual line and the third horizontal virtual line.

In some embodiments, among the plurality of gate polysilicon contact holes, a second gate polysilicon contact hole may be formed so as to extend along the first axial direction between the intersection of the first vertical virtual line and the fourth horizontal virtual line and the intersection of the fourth horizontal virtual line and the second vertical virtual line.

In some embodiments, among the plurality of shielded polysilicon contact holes, a second shield polysilicon contact hole may be formed so as to extend along the first axial direction between the intersection of the second vertical virtual line and the third horizontal virtual line and the intersection of the third horizontal virtual line and the third vertical virtual line.

In some embodiments, the semiconductor device may further include a second source contact hole that is formed so as to extend along the second axial direction between a portion of the trench region extending in the second axial direction along the first vertical virtual line and a portion extending in the second axial direction along the second vertical virtual line.

In some embodiments, the plurality of gate polysilicon contact holes may be formed such that the upper surface of a gate polysilicon layer formed inside along the trench region and gate polysilicon contact metals can be in contact.

In some embodiments, the plurality of shielded polysilicon contact holes may be formed such that the upper surface of a shielded polysilicon layer formed inside along the trench region and shield polysilicon contact metals can be in contact.

In some embodiments, a plurality of gate polysilicon contact holes and a plurality of shielded polysilicon contact holes may be formed only along the first axial direction, and are not formed along the second axial direction.

In a semiconductor device according to an embodiment, on the upper surface of the semiconductor device, a first horizontal virtual line, a second horizontal virtual line, and a third horizontal virtual line which extend in parallel with one another along a first axial direction may be defined, and on the upper surface of the semiconductor device, a first vertical virtual line, a second vertical virtual line, and a third vertical virtual line which extend in parallel with one another along a second axial direction perpendicular to the first axial direction may be defined, and the semiconductor device may include a trench region, a gate contact region, and a source contact region, and the trench region may be formed so as to extend in the second axial direction along the first vertical virtual line, extend along the first axial direction from the intersection of the first vertical virtual line and the first horizontal virtual line, extend along the first axial direction from the intersection of the first vertical virtual line and the third horizontal virtual line, extend along the second axial direction from the intersection of the first horizontal virtual line and the second vertical virtual line to the intersection of the third horizontal virtual line and the second vertical virtual line, and extend along the first axial direction from the intersection of the second vertical virtual line and the second horizontal virtual line, and on the trench region, a plurality of gate polysilicon contact holes and a plurality of shielded polysilicon contact holes may be formed.

In some embodiments, among the plurality of gate polysilicon contact holes, a first gate polysilicon contact hole may be formed so as to extend along the first axial direction between the intersection of the first vertical virtual line and the first horizontal virtual line and the intersection of the first horizontal virtual line and the second vertical virtual line, and among the plurality of gate polysilicon contact holes, a second gate polysilicon contact hole may be formed so as to extend along the first axial direction between the intersection of the first vertical virtual line and the third horizontal virtual line and the intersection of the third horizontal virtual line and the second vertical virtual line.

In some embodiments, among the plurality of shielded polysilicon contact holes, a first shielded polysilicon contact hole may be formed so as to extend along the first axial direction between the intersection of the second vertical virtual line and the second horizontal virtual line and the intersection of the second horizontal virtual line and the third vertical virtual line.

In some embodiments, the semiconductor device may further include a first source contact hole that is formed so as to extend along the second axial direction between a portion of the trench region extending in the second axial direction along the first vertical virtual line and a portion extending in the second axial direction along the second vertical virtual line, and a second source contact hole that is formed so as to extend along the second axial direction between a portion of the trench region extending in the second axial direction along the second vertical virtual line and a portion extending in the second axial direction along the third vertical virtual line.

In some embodiments, among the plurality of gate polysilicon contact holes, a first gate polysilicon contact hole may be formed so as to extend along the first axial direction between the intersection of the second vertical virtual line and the second horizontal virtual line and the intersection of the second horizontal virtual line and the third vertical virtual line.

In some embodiments, among the plurality of shielded polysilicon contact holes, a first shielded polysilicon contact hole may be formed so as to extend along the first axial direction between the intersection of the first vertical virtual line and the first horizontal virtual line and the intersection of the first horizontal virtual line and the second vertical virtual line, and among the plurality of gate polysilicon contact holes, a second gate polysilicon contact hole may be formed so as to extend along the first axial direction between the intersection of the first vertical virtual line and the third horizontal virtual line and the intersection of the third horizontal virtual line and the second vertical virtual line.

In some embodiments, the semiconductor device may further include a first source contact hole that is formed so as to extend along the second axial direction between a portion of the trench region extending in the second axial direction along the first vertical virtual line and a portion extending in the second axial direction along the second vertical virtual line, and the semiconductor device may further include a second source contact hole that is formed so as to extend along the second axial direction between a portion of the trench region extending in the second axial direction along the second vertical virtual line and a portion extending in the second axial direction along the third vertical virtual line.

In some embodiments, the semiconductor device may further include a gate bus where the plurality of gate polysilicon contact holes is formed along the second horizontal virtual line.

In some embodiments, a plurality of gate polysilicon contact holes and a plurality of shielded polysilicon contact holes may be formed only along the first axial direction, and may not be formed along the second axial direction.

### BRIEF DESCRIPTION OF THE DRAWINGS

FIG. 1 is a drawing for explaining a semiconductor device according to an embodiment.

FIG. 2 is a drawing for explaining a semiconductor device according to an embodiment.

FIG. 3 is a drawing for explaining a semiconductor device according to an embodiment.

FIG. 4 is a drawing for explaining a semiconductor device according to an embodiment.

FIG. 5 is a drawing for explaining a semiconductor device according to an embodiment.

FIGS. 6 to 17 are drawings for explaining a method of manufacturing a semiconductor device according to an embodiment.

### DETAILED DESCRIPTION

In the following detailed description, only certain embodiments of the present invention have been shown and described, simply by way of illustration. However, the present invention can be variously implemented and is not limited to the following embodiments. The drawings and description are to be regarded as illustrative in nature and not restrictive. Like reference numerals designate like elements throughout the specification.

Throughout the specification and the claims, when a part is referred to as including or comprising some constituent elements, it will be understood to imply the inclusion of stated elements but not the exclusion of any other elements, unless explicitly described to the contrary.

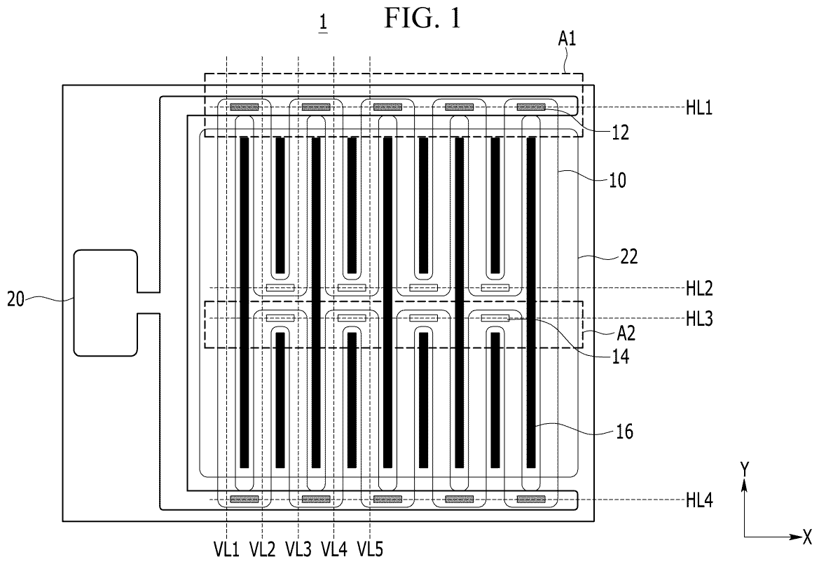

FIG. 1 is a drawing for explaining a semiconductor device according to an embodiment.

A semiconductor device 1 according to an embodiment may be a trench power MOSFET which is characterized by a trench structure. And FIG. 1 illustrates the upper surface of the semiconductor device 1. In the semiconductor device 1, particularly, one trench cell may include a gate polysilicon layer and a shielded polysilicon layer. The gate polysilicon layer and the shielded polysilicon layer may form a stack structure, and the gate polysilicon layer and the shielded polysilicon layer may be electrically insulated by an oxide film, for example, a gate oxide film. In some embodiments, the gate polysilicon layer and the shielded polysilicon layer both are formed as n⁺ polysilicon layers doped with n-type impurities; however, the scope of the present invention is not limited thereto. Referring to FIG. 1, the semiconductor device 1 may include a trench region 10, a plurality of gate polysilicon contact holes 12, a plurality of shielded polysilicon contact holes 14, a plurality of source contact holes 16, a gate contact region 20, and a source contact region 22.

For clarity of description, on the upper surface of the semiconductor device 1, a plurality of horizontal virtual lines and a plurality of vertical virtual lines perpendicular to the plurality of horizontal virtual lines may be defined. As shown in the drawing, on the upper surface of the semiconductor device 1, a plurality of horizontal virtual lines HL1 to HL4 which extends in parallel with one another along a first axial direction (the X-axis direction in the drawing) may be defined. Also, on the upper surface of the semiconductor device 1, a plurality of vertical virtual lines VL1 to VL5 which extends in parallel with one another along a second axial direction (the Y-axis direction in the drawing) perpendicular to the first axial direction the may be defined. It is apparent that besides the numbers of horizontal virtual lines and vertical virtual lines shown in the drawing, horizontal virtual lines and vertical virtual lines may be further defined on the upper surface of the semiconductor device 1 although omitted for visual clarity of the drawing.

In the substrate of the semiconductor device 1, a trench may be formed, and the trench region 10 represents the trench projected onto the upper surface. The gate polysilicon layer and the shielded polysilicon layer which are formed inside the trench may also be formed inside the semiconductor device 1 along the trench region 10. In some embodiments, the trench region 10 may be formed so as to continuously extend along the first axial direction and the second axial direction, without forming any isolated area.

In other words, the trench region 10 may be formed so as to continuously extend along the plurality of horizontal virtual lines HL1 to HL4 and the plurality of vertical virtual lines VL1 to VL5. Specifically, the trench region 10 may be formed so as to extend in the second axial direction along the first vertical virtual line VL1, extend in the first axial direction from the intersection of the first vertical virtual line VL1 and the first horizontal virtual line HL1 to the intersection of the first horizontal virtual line HL1 and the second vertical virtual line VL2, extend in the second axial direction from the intersection of the first horizontal virtual line HL1 and the second vertical virtual line VL2 to the intersection of the second vertical virtual line VL2 and the second horizontal virtual line HL2, and extend in the first axial direction from the intersection of the second vertical virtual line VL2 and the second horizontal virtual line HL2 to the intersection of the third vertical virtual line VL3 and the second horizontal virtual line HL2. Further, the trench region 10 may be formed so as to extend in the second axial direction from the intersection of the third vertical virtual line VL3 and the second horizontal virtual line HL2 to the intersection of the third vertical virtual line VL3 and the first horizontal virtual line HL1, extend in the first axial direction from the intersection of the third vertical virtual line VL3 and the first horizontal virtual line HL1 to the intersection of the first horizontal virtual line HL1 and the fourth vertical virtual line VL4, extend in the second axial direction from the intersection of the first horizontal virtual line HL1 and the fourth vertical virtual line VL4 to the intersection of the fourth vertical virtual line VL4 and the second horizontal virtual line HL2, and extend in the first axial direction from the intersection of the fourth vertical virtual line VL4 and the second horizontal virtual line HL2 to the intersection of the fifth vertical virtual line VL5 and the second horizontal virtual line HL2. Meanwhile, the trench region 10 may be formed so as to extend in the first axial direction from the intersection of the first vertical virtual line VL1 and the fourth horizontal virtual line HL4 to the intersection of the fourth horizontal virtual line HL4 and the second vertical virtual line VL2, extend in the second axial direction from the intersection of the fourth horizontal virtual line HL4 and the second vertical virtual line VL2 to the intersection of the second vertical virtual line VL2 and the third horizontal virtual line HL3, and extend in the first axial direction from the intersection of the second vertical virtual line VL2 and the third horizontal virtual line HL3 to the intersection of the third horizontal virtual line HL3 and the third vertical virtual line VL3. Subsequently, the trench region 10 may be formed so as to extend in the second axial direction from the intersection of the third vertical virtual line VL3 and the third horizontal virtual line HL3 to the intersection of the third vertical virtual line VL3 and the fourth horizontal virtual line HL4, extend in the first axial direction from the intersection of the third vertical virtual line VL3 and the fourth horizontal virtual line HL4 to the intersection of the fourth horizontal virtual line HL4 and the fourth vertical virtual line VL4, extend in the second axial direction from the intersection of the fourth horizontal virtual line HL4 and the fourth vertical virtual line VL4 to the intersection of the fourth vertical virtual line VL4 and the third horizontal virtual line HL3, and extend in the first axial direction from the intersection of the fourth vertical virtual line VL4 and the third horizontal virtual line HL3 to the intersection of the fifth vertical virtual line VL5 and the third horizontal virtual line HL3. By repeating this process, the trench region 10 having a shape as shown in the drawing may be formed.

On the trench region 10, the plurality of gate polysilicon contact holes 12 and the plurality of shielded polysilicon contact holes 14 may be formed. On the semiconductor device 1, the gate contact region 20 may be defined, and in the gate contact region 20, the plurality of gate polysilicon contact holes 12 may be formed. Meanwhile, on the semiconductor device 1, the source contact region 22 may be defined, and in the source contact region 22, the plurality of shielded polysilicon contact holes 14 and the plurality of source contact holes 16 may be formed.

The plurality of gate polysilicon contact holes 12 may expose some portions of the upper surface of the gate polysilicon layer formed inside the semiconductor device 1 along the trench region 10. The plurality of exposed portions of the upper surface of the gate polysilicon layer may be connected to one another through first metals, and may be connected to gate pads. Here, the first metals may be referred to as gate polysilicon contact metals. In other words, the plurality of gate polysilicon contact holes 12 may be formed such that the upper surface of the gate polysilicon layer formed inside along the trench region 10 and the gate polysilicon contact metals can be in contact. In some embodiments, the plurality of gate polysilicon contact holes 12 may be formed so as to extend only along the first axial direction, and may not extend along the second axial direction.

Specifically, among the plurality of gate polysilicon contact holes 12, a first gate polysilicon contact hole may be formed so as to extend along the first axial direction between the intersection of the first vertical virtual line VL1 and the first horizontal virtual line HL1 and the intersection of the first horizontal virtual line HL1 and the second vertical virtual line VL2. Next, a second gate polysilicon contact hole may be formed so as to extend along the first axial direction between the intersection of the third vertical virtual line VL3 and the first horizontal virtual line HL1 and the intersection of the first horizontal virtual line HL1 and the fourth vertical virtual line VL4. Meanwhile, among the plurality of gate polysilicon contact holes 12, a third gate polysilicon contact hole may be formed so as to extend along the first axial direction between the intersection of the first vertical virtual line VL1 and the fourth horizontal virtual line HL4 and the intersection of the fourth horizontal virtual line HL4 and the second vertical virtual line VL2. Next, a fourth gate polysilicon contact hole may be formed so as to extend along the first axial direction between the intersection of the third vertical virtual line VL3 and the fourth horizontal virtual line HL4 and the intersection of the fourth horizontal virtual line HL4 and the fourth vertical virtual line VL4. By repeating this process, the plurality of gate polysilicon contact holes 12 having a shape as shown in the drawing may be formed.

The plurality of shielded polysilicon contact holes 14 may expose some portions of the upper surface of the shielded polysilicon layer formed inside the semiconductor device 1 along the trench region 10. The plurality of exposed portions of the upper surface of the shielded polysilicon layer may be connected to one another through second metals. Here, the second metals may be referred to as shielded polysilicon contact metals. In other words, the plurality of shielded polysilicon contact holes 14 may be formed such as the upper surface of the shielded polysilicon layer formed inside along the trench region 10 and the shielded polysilicon contact metals can be in contact. In some embodiments, similar to the plurality of gate polysilicon contact holes 12, the plurality of shielded polysilicon contact holes 14 may be formed so as to extend only along the first axial direction, and may not extend along the second axial direction.

Specifically, among the plurality of shielded polysilicon contact holes 14, a first shielded polysilicon contact hole may be formed so as to extend along the first axial direction between the intersection of the second vertical virtual line VL2 and the second horizontal virtual line HL2 and the intersection of the second horizontal virtual line HL2 and the third vertical virtual line VL3. Next, a second shielded polysilicon contact hole may be formed so as to extend along the first axial direction between the intersection of the fourth vertical virtual line VL4 and the second horizontal virtual line HL2 and the intersection of the second horizontal virtual line HL2 and the fifth vertical virtual line VL5. Meanwhile, among the plurality of shielded polysilicon contact holes 14, a second shielded polysilicon contact hole may be formed so as to extend along the first axial direction between the intersection of the second vertical virtual line VL2 and the third horizontal virtual line HL3 and the intersection of the third horizontal virtual line HL3 and the third vertical virtual line VL3. Next, a fourth shielded polysilicon contact hole may be formed so as to extend along the first axial direction between the intersection of the fourth vertical virtual line VL4 and the third horizontal virtual line HL3 and the intersection of the third horizontal virtual line HL3 and the fifth vertical virtual line VL5. By repeating this process, the plurality of shielded polysilicon contact holes 14 having a shape as shown in the drawing may be formed.

In some embodiments, the plurality of gate polysilicon contact holes 12 and the plurality of shielded polysilicon contact holes 14 may be formed so as not to overlap each other in the second axial direction. In other words, the plurality of gate polysilicon contact holes 12 and the plurality of shielded polysilicon contact holes 14 may be formed so as not to face each other in the second axial direction. Further, the plurality of gate polysilicon contact holes 12 may be formed so as to face each other in the second axial direction, and the plurality of shielded polysilicon contact holes 14 may be formed so as not to face each other in the second axial direction.

The plurality of source contact holes 16 may expose trench cells and the upper surfaces of source contact layers which are formed between neighboring trench cells. The source contact layers may be, for example, layers doped with high-concentration n-type impurity ions. The exposed upper surfaces of the plurality of source contact layer may be connected to one another through third metals. Here, the third metals may be referred to as source contact metals. In other words, the plurality of source contact holes 16 may be formed such that the upper surfaces of the source contact layers formed between some portions of the trench region 10 and the source contact metals can be in contact with each other. In some embodiments, the plurality of source contact holes 16 may be formed so as to extend only along the second axial direction, and may not extend along the first axial direction.

Specifically, among the plurality of source contact holes 16, a first source contact hole may be formed so as to extend along the second axial direction between the first gate polysilicon contact hole and the third gate polysilicon contact hole between the portion of the trench region 10 extending in the second axial direction along the first vertical virtual line VL1 and the portion extending in the second axial direction along the second vertical virtual line VL2. Further, among the plurality of source contact holes 16, a second source contact hole may be formed so as to extend along the second axial direction between the first horizontal virtual line HL1 and the first shielded polysilicon contact hole between the portion of the trench region 10 extending in the second axial direction along the second vertical virtual line VL2 and the portion extending in the second axial direction along the third vertical virtual line VL3. Meanwhile, among the plurality of source contact holes 16, a second source contact hole may be formed so as to extend along the second axial direction between the third shielded polysilicon contact hole and the fourth horizontal virtual line HL4 between the portion of the trench region 10 extending in the second axial direction along the second vertical virtual line VL2 and the portion extending in the second axial direction along the third vertical virtual line VL3. By repeating this process, the plurality of source contact holes 16 having a shape as shown in the drawing may be formed.

According to the present embodiment, a region where contacts for the shielded polysilicon layer are formed inside the source contact region 22 can be implemented without the need to further form a region where contacts for the shielded polysilicon layer are formed besides a region (i.e., the gate contact region 20) where contacts for the gate polysilicon layer are formed. Accordingly, it is possible to maximize the substantial area of an active region. This is because when a region where contacts for the shielded polysilicon layer are formed needs to be further formed in a place other than the gate contact region 20 and the source contact region 22, in a semiconductor device having the same size, a loss occurs in the area of the active region. As described above, as the ratio of the active region increases, the device characteristics of the semiconductor device can be improved.

Further, by the structure according to the present embodiment, the sizes of the plurality of gate polysilicon contact holes 12 and the plurality of shielded polysilicon contact holes 14 may be flexibly adjusted. In other words, it is easy to increase the sizes of the plurality of gate polysilicon contact holes 12 and the plurality of shielded polysilicon contact holes 14 depending on a specific design purpose or design environment, and even when there is a restriction that the width of the trench region 10 should be designed to be narrow, there is no problem in forming the plurality of gate polysilicon contact holes 12 and the plurality of shielded polysilicon contact holes 14. In other words, there is a great advantage in terms of design flexibility.

In addition, since the direction of the trench where the plurality of gate polysilicon contact holes 12 and the plurality of shielded polysilicon contact holes 14 are formed is perpendicular to the direction of the trench of the active region, it is possible to prevent or minimize occurrence of a warpage phenomenon that may occur in thin substrates.

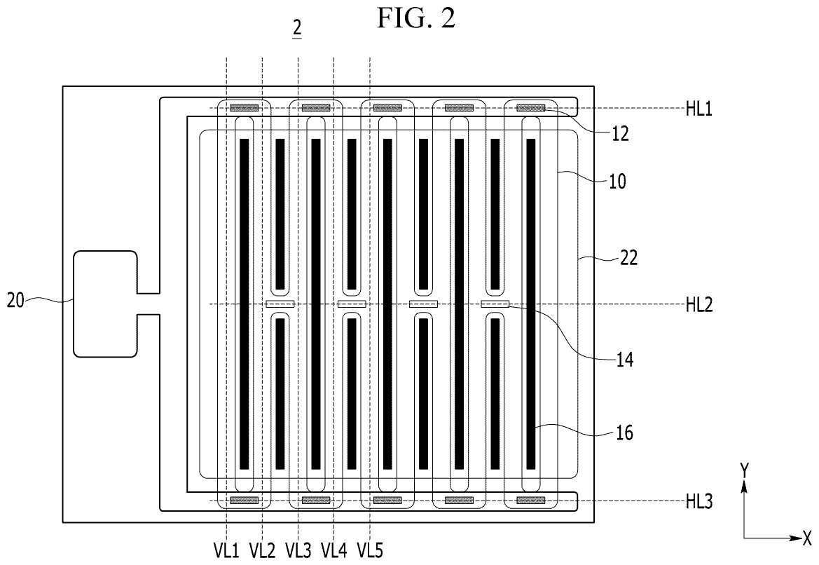

FIG. 2 is a drawing for explaining a semiconductor device according to an embodiment.

Referring to FIG. 2, a semiconductor device 2 according to an embodiment is different from the semiconductor device 1 in that the patterns of the trench region 10 and the plurality of shielded polysilicon contact holes 14 among the patterns of the semiconductor device 1 described in relation to FIG. 1. Hereinafter, the difference from the semiconductor device 1 will be mainly described, and in the range where the trench region and the shielded polysilicon contact holes 14 are not disposed, the above description related to the semiconductor device 1 may also be applied to the semiconductor device 2.

For clarity of description, on the upper surface of the semiconductor device 2, a plurality of horizontal virtual lines HL1 to HL3 which extends in parallel with one another along the first axial direction may be defined. Further, on the upper surface of the semiconductor device 2, a plurality of vertical virtual lines VL1 to VL5 which extends in parallel with one another along the second axial direction may be defined. It is apparent that besides the numbers of horizontal virtual lines and vertical virtual lines shown in the drawing, horizontal virtual lines and vertical virtual lines may be further defined on the upper surface of the semiconductor device 2 although omitted for visual clarity of the drawing.

The trench region 10 may be formed so as to continuously extend along the plurality of horizontal virtual lines HL1 to HL3 and the plurality of vertical virtual lines VL1 to VL5. Specifically, the trench region 10 may be formed so as to extend in the second axial direction along the first vertical virtual line VL1, extend in the first axial direction from the intersection of the first vertical virtual line VL1 and the first horizontal virtual line HL1 to the intersection of the first horizontal virtual line HL1 and the second vertical virtual line VL2, extend in the first axial direction from the intersection of the first vertical virtual line VL1 and the third horizontal virtual line HL3 to the intersection of the third horizontal virtual line HL3 and the second vertical virtual line VL2, extend in the second axial direction from the intersection of the first horizontal virtual line HL1 and the second vertical virtual line VL2 to the intersection of the second vertical virtual line VL2 and the third horizontal virtual line HL3, and extend in the first axial direction from the intersection of the second vertical virtual line VL2 and the second horizontal virtual line HL2 to the intersection of the third vertical virtual line VL3 and the second horizontal virtual line HL2. Subsequently, the trench region 10 may be formed so as to extend in the second axial direction along the third vertical virtual line VL3, extend in the first axial direction from the intersection of the third vertical virtual line VL3 and the first horizontal virtual line HL1 to the intersection of the first horizontal virtual line HL1 and the fourth vertical virtual line VL4, extend in the first axial direction from the intersection of the third vertical virtual line VL3 and the third horizontal virtual line HL3 to the intersection of the third horizontal virtual line HL3 and the fourth vertical virtual line VL4, extend in the second axial direction from the intersection of the first horizontal virtual line HL1 and the fourth vertical virtual line VL4 to the intersection of the fourth vertical virtual line VL4 and the third horizontal virtual line HL3, and extend in the first axial direction from the intersection of the fourth vertical virtual line VL4 and the second horizontal virtual line HL2 to the intersection of the fifth vertical virtual line VL5 and the second horizontal virtual line HL2. By repeating this process, the trench region 10 having a shape as shown in the drawing may be formed.

Among the plurality of gate polysilicon contact holes 12, a first gate polysilicon contact hole may be formed so as to extend along the first axial direction between the intersection of the first vertical virtual line VL1 and the first horizontal virtual line HL1 and the intersection of the first horizontal virtual line HL1 and the second vertical virtual line VL2. Next, a second gate polysilicon contact hole may be formed so as to extend along the first axial direction between the intersection of the third vertical virtual line VL3 and the first horizontal virtual line HL1 and the intersection of the first horizontal virtual line HL1 and the fourth vertical virtual line VL4. Meanwhile, among the plurality of gate polysilicon contact holes 12, a third gate polysilicon contact hole may be formed so as to extend along the first axial direction between the intersection of the first vertical virtual line VL1 and the third horizontal virtual line HL3 and the intersection of the third horizontal virtual line HL3 and the second vertical virtual line VL2. Next, a fourth gate polysilicon contact hole may be formed so as to extend along the first axial direction between the intersection of the third vertical virtual line VL3 and the third horizontal virtual line HL3 and the intersection of the third horizontal virtual line HL3 and the fourth vertical virtual line VL4. By repeating this process, the plurality of gate polysilicon contact holes 12 having a shape as shown in the drawing may be formed.

Among the plurality of shielded polysilicon contact holes 14, a first shielded polysilicon contact hole may be formed so as to extend along the first axial direction between the intersection of the second vertical virtual line VL2 and the second horizontal virtual line HL2 and the intersection of the second horizontal virtual line HL2 and the third vertical virtual line VL3. Next, a second shielded polysilicon contact hole may be formed so as to extend along the first axial direction between the intersection of the fourth vertical virtual line VL4 and the second horizontal virtual line HL2 and the intersection of the second horizontal virtual line HL2 and the fifth vertical virtual line VL5. By repeating this process, the plurality of shielded polysilicon contact holes 14 having a shape as shown in the drawing may be formed.

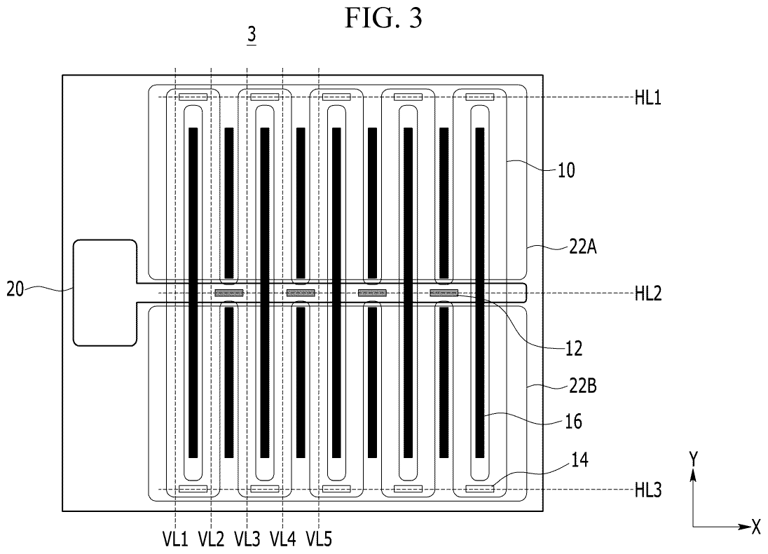

FIG. 3 is a drawing for explaining a semiconductor device according to an embodiment.

Referring to FIG. 3, a semiconductor device 3 according to an embodiment is different from the semiconductor device 2 described in relation to FIG. 2 in the patterns of the plurality of gate polysilicon contact holes 12, the plurality of shielded polysilicon contact holes 14, the gate contact region 20, and the source contact region 22 among the patterns of the semiconductor device 2, and is different from the semiconductor device 2 in that a plurality of gate polysilicon contact holes 12 is formed along a second horizontal virtual line HL2. Hereinafter, the difference from the semiconductor device 2 will be mainly described, and in the range where the gate polysilicon contact holes, the shielded polysilicon contact holes, the gate contact region, and the source contact region are not disposed, the above description related to the semiconductor device 2 may also be applied to the semiconductor device 3.

For clarity of description, on the upper surface of the semiconductor device 3, a plurality of horizontal virtual lines HL1 to HL3 which extends in parallel with one another along the first axial direction may be defined. Further, on the upper surface of the semiconductor device 3, a plurality of vertical virtual lines VL1 to VL5 which extends in parallel with one another along the second axial direction may be defined. It is apparent that besides the numbers of horizontal virtual lines and vertical virtual lines shown in the drawing, horizontal virtual lines and vertical virtual lines may be further defined on the upper surface of the semiconductor device 3 although omitted for visual clarity of the drawing.

Among the plurality of gate polysilicon contact holes 12, the first gate polysilicon contact hole may be formed so as to extend along the first axial direction between the intersection of the second vertical virtual line VL2 and the second horizontal virtual line HL2 and the intersection of the second horizontal virtual line HL2 and the third vertical virtual line VL3. Next, the second gate polysilicon contact hole may be formed so as to extend along the first axial direction between the intersection of the fourth vertical virtual line VL4 and the second horizontal virtual line HL2 and the intersection of the second horizontal virtual line HL2 and the fifth vertical virtual line VL5. By repeating this process, the plurality of gate polysilicon contact holes 12 having a shape as shown in the drawing may be formed.

Among the plurality of shielded polysilicon contact holes 14, the first shielded polysilicon contact hole may be formed so as to extend along the first axial direction between the intersection of the first vertical virtual line VL1 and the first horizontal virtual line HL1 and the intersection of the first horizontal virtual line HL1 and the second vertical virtual line VL2. Next, the second shielded polysilicon contact hole may be formed so as to extend along the first axial direction between the intersection of the third vertical virtual line VL3 and the first horizontal virtual line HL1 and the intersection of the first horizontal virtual line HL1 and the fourth vertical virtual line VL4. Meanwhile, among the plurality of shielded polysilicon contact holes 14, the third shielded polysilicon contact hole may be formed so as to extend along the first axial direction between the intersection of the first vertical virtual line VL1 and the third horizontal virtual line HL3 and the intersection of the third horizontal virtual line HL3 and the second vertical virtual line VL2. Next, the fourth shielded polysilicon contact hole may be formed so as to extend along the first axial direction between the intersection of the third vertical virtual line VL3 and the third horizontal virtual line HL3 and the intersection of the third horizontal virtual line HL3 and the fourth vertical virtual line VL4. By repeating this process, the plurality of shielded polysilicon contact holes 14 having a shape as shown in the drawing may be formed.

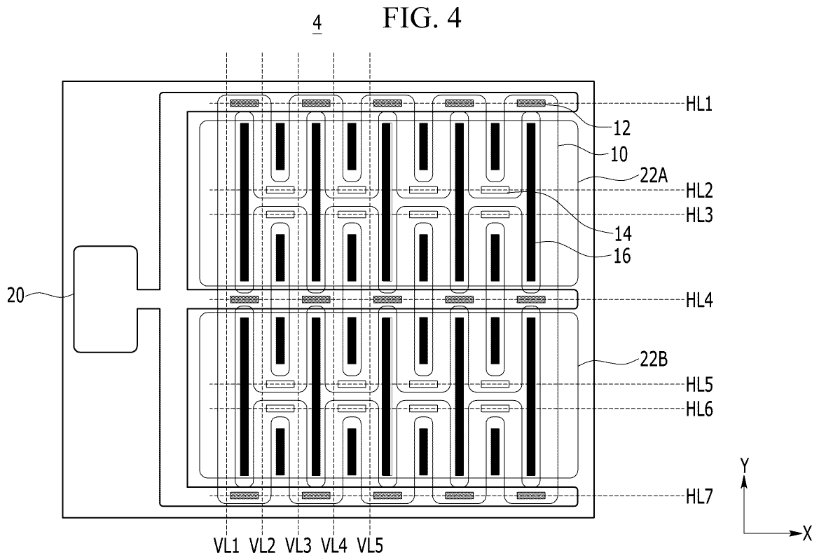

FIG. 4 is a drawing for explaining a semiconductor device according to an embodiment.

Referring to FIG. 4, a semiconductor device 4 according to an embodiment is different from the semiconductor device 1 in that the patterns of the semiconductor device 1 described in relation to FIG. 1 are disposed at the upper portion and the lower portion, and a gate bus which extends along the fourth horizontal virtual line HL4 between the upper portion and the low portion is additionally formed. In this case, on the gate bus additionally formed, some portions of the plurality of gate polysilicon contact holes 12 may be disposed. As the gate bus which extend along the fourth horizontal virtual line HL4 is additionally formed as described above, the switching speed may be increased. For example, as compared to the embodiments described in relation to FIGS. 1 to 3, the gate internal resistance is approximately halved, whereby the switching speed is increased. Hereinafter, the difference from the semiconductor device 1 will be mainly described, and in the range where the gate bus is not disposed, the above description related to the semiconductor device 1 may also be applied to the semiconductor device 4.

For clarity of description, on the upper surface of the semiconductor device 4, a plurality of horizontal virtual lines HL1 to HL7 which extends in parallel with one another along the first axial direction may be defined. Further, on the upper surface of the semiconductor device 4, a plurality of vertical virtual lines VL1 to VL5 which extends in parallel with one another along the second axial direction may be defined. It is apparent that besides the numbers of horizontal virtual lines and vertical virtual lines shown in the drawing, horizontal virtual lines and vertical virtual lines may be further defined on the upper surface of the semiconductor device 4 although omitted for visual clarity of the drawing.

The trench region 10 may be formed so as to continuously extend along the plurality of horizontal virtual lines HL1 to HL7 and the plurality of vertical virtual lines VL1 to VL5. Specifically, the trench region 10 may be formed so as to extend in the second axial direction along the first vertical virtual line VL1, extend along the first axial direction from the intersection of the first vertical virtual line VL1 and the first horizontal virtual line HL1 to the intersection of the first horizontal virtual line HL1 and the second vertical virtual line VL2, extend along the second axial direction from the intersection of the first horizontal virtual line HL1 and the second vertical virtual line VL2 to the intersection of the second vertical virtual line VL2 and the second horizontal virtual line HL2, and extend along the first axial direction from the intersection of the second vertical virtual line VL2 and the second horizontal virtual line HL2 to the intersection of the third vertical virtual line VL3 and the second horizontal virtual line HL2. Subsequently, the trench region 10 may be formed so as to extend along the second axial direction from the intersection of the third vertical virtual line VL3 and the second horizontal virtual line HL2 to the intersection of the third vertical virtual line VL3 and the first horizontal virtual line HL1, extend along the first axial direction from the intersection of the third vertical virtual line VL3 and the first horizontal virtual line HL1 to the intersection of the first horizontal virtual line HL1 and the fourth vertical virtual line VL4, extend along the second axial direction from the intersection of the first horizontal virtual line HL1 and the fourth vertical virtual line VL4 to the intersection of the fourth vertical virtual line VL4 and the second horizontal virtual line HL2, and extend along the first axial direction from the intersection of the fourth vertical virtual line VL4 and the second horizontal virtual line HL2 to the intersection of the fifth vertical virtual line VL5 and the second horizontal virtual line HL2. Meanwhile, the trench region 10 may be formed so as to extend along the first axial direction from the intersection of the first vertical virtual line VL1 and the fourth horizontal virtual line HL4 to the intersection of the fourth horizontal virtual line HL4 and the second vertical virtual line VL2, extend along the second axial direction from the intersection of the fourth horizontal virtual line HL4 and the second vertical virtual line VL2 to the intersection of the second vertical virtual line VL2 and the third horizontal virtual line HL3, and extend along the first axial direction from the intersection of the second vertical virtual line VL2 and the third horizontal virtual line HL3 to the intersection of the third horizontal virtual line HL3 and the third vertical virtual line VL3. Subsequently, the trench region 10 may be formed so as to extend in the second axial direction from the intersection of the third vertical virtual line VL3 and the third horizontal virtual line HL3 to the intersection of the third vertical virtual line VL3 and the fourth horizontal virtual line HL4, extend in the first axial direction from the intersection of the third vertical virtual line VL3 and the fourth horizontal virtual line HL4 to the intersection of the fourth horizontal virtual line HL4 and the fourth vertical virtual line VL4, extend in the second axial direction from the intersection of the fourth horizontal virtual line HL4 and the fourth vertical virtual line VL4 to the intersection of the fourth vertical virtual line VL4 and the third horizontal virtual line HL3, and extend in the first axial direction from the intersection of the fourth vertical virtual line VL4 and the third horizontal virtual line HL3 to the intersection of the fifth vertical virtual line VL5 and the third horizontal virtual line HL3.

Meanwhile, the trench region 10 may be formed so as to extend along the second axial direction from the intersection of the fourth horizontal virtual line HL4 and the second vertical virtual line VL2 to the intersection of the second vertical virtual line VL2 and the fifth horizontal virtual line HL5 and extend along the first axial direction from the intersection of the second vertical virtual line VL2 and the fifth horizontal virtual line HL5 to the intersection of the third vertical virtual line VL3 and the fifth horizontal virtual line HL5. Subsequently, the trench region 10 may be formed so as to extend along the second axial direction from the intersection of the third vertical virtual line VL3 and the fifth horizontal virtual line HL5 to the intersection of the third vertical virtual line VL3 and the fourth horizontal virtual line HL4. Meanwhile, the trench region 10 may be formed so as to extend along the first axial direction from the intersection of the first vertical virtual line VL1 and the seventh horizontal virtual line HL7 to the intersection of the seventh horizontal virtual line HL7 and the second vertical virtual line VL2, extend along the second axial direction from the intersection of the seventh horizontal virtual line HL7 and the second vertical virtual line VL2 to the intersection of the second vertical virtual line VL2 and the sixth horizontal virtual line HL6, and extend along the first axial direction from the intersection of the second vertical virtual line VL2 and the sixth horizontal virtual line HL6 to the intersection of the sixth horizontal virtual line HL6 and the third vertical virtual line VL3. Subsequently, the trench region 10 may be formed so as to extend along the second axial direction from the intersection of the third vertical virtual line VL3 and the sixth horizontal virtual line HL6 to the intersection of the third vertical virtual line VL3 and the seventh horizontal virtual line HL7. By repeating this process, the trench region 10 having a shape as shown in the drawing may be formed.

Among the plurality of gate polysilicon contact holes 12, a first gate polysilicon contact hole may be formed so as to extend along the first axial direction between the intersection of the first vertical virtual line VL1 and the first horizontal virtual line HL1 and the intersection of the first horizontal virtual line HL1 and the second vertical virtual line VL2. Next, a second gate polysilicon contact hole may be formed so as to extend along the first axial direction between the intersection of the third vertical virtual line VL3 and the first horizontal virtual line HL1 and the intersection of the first horizontal virtual line HL1 and the fourth vertical virtual line VL4. Meanwhile, among the plurality of gate polysilicon contact holes 12, a third gate polysilicon contact hole may be formed so as to extend along the first axial direction between the intersection of the first vertical virtual line VL1 and the fourth horizontal virtual line HL4 and the intersection of the fourth horizontal virtual line HL4 and the second vertical virtual line VL2. Next, a fourth gate polysilicon contact hole may be formed so as to extend along the first axial direction between the intersection of the third vertical virtual line VL3 and the fourth horizontal virtual line HL4 and the intersection of the fourth horizontal virtual line HL4 and the fourth vertical virtual line VL4. Meanwhile, among the plurality of gate polysilicon contact holes 12, a fifth gate polysilicon contact hole may be formed so as to extend along the first axial direction between the intersection of the first vertical virtual line VL1 and the seventh horizontal virtual line HL7 and the intersection of the seventh horizontal virtual line HL7 and the second vertical virtual line VL2. Next, a sixth gate polysilicon contact hole may be formed so as to extend along the first axial direction between the intersection of the third vertical virtual line VL3 and the seventh horizontal virtual line HL7 and the intersection of the seventh horizontal virtual line HL7 and the fourth vertical virtual line VL4. By repeating this process, the plurality of gate polysilicon contact holes 12 having a shape as shown in the drawing may be formed.

Among the plurality of shielded polysilicon contact holes 14, a first shielded polysilicon contact hole may be formed so as to extend along the first axial direction between the intersection of the second vertical virtual line VL2 and the second horizontal virtual line HL2 and the intersection of the second horizontal virtual line HL2 and the third vertical virtual line VL3. Next, a second shielded polysilicon contact hole may be formed so as to extend along the first axial direction between the intersection of the fourth vertical virtual line VL4 and the second horizontal virtual line HL2 and the intersection of the second horizontal virtual line HL2 and the fifth vertical virtual line VL5. Meanwhile, among the plurality of shielded polysilicon contact holes 14, a second shielded polysilicon contact hole may be formed so as to extend along the first axial direction between the intersection of the second vertical virtual line VL2 and the third horizontal virtual line HL3 and the intersection of the third horizontal virtual line HL3 and the third vertical virtual line VL3. Next, a fourth shielded polysilicon contact hole may be formed so as to extend along the first axial direction between the intersection of the fourth vertical virtual line VL4 and the third horizontal virtual line HL3 and the intersection of the third horizontal virtual line HL3 and the fifth vertical virtual line VL5. Further, among the plurality of shielded polysilicon contact holes 14, a fifth shielded polysilicon contact hole may be formed so as to extend along the first axial direction between the intersection of the second vertical virtual line VL2 and the fifth horizontal virtual line HL5 and the intersection of the fifth horizontal virtual line HL5 and the third vertical virtual line VL3. Next, a sixth shielded polysilicon contact hole may be formed so as to extend along the first axial direction between the intersection of the fourth vertical virtual line VL4 and the fifth horizontal virtual line HL5 and the intersection of the fifth horizontal virtual line HL5 and the fifth vertical virtual line VL5. Meanwhile, among the plurality of shielded polysilicon contact holes 14, a seventh shielded polysilicon contact hole may be formed so as to extend along the first axial direction between the intersection of the second vertical virtual line VL2 and the sixth horizontal virtual line HL6 and the intersection of the sixth horizontal virtual line HL6 and the third vertical virtual line VL3. Next, an eighth shielded polysilicon contact hole may be formed so as to extend along the first axial direction between the intersection of the fourth vertical virtual line VL4 and the sixth horizontal virtual line HL6 and the intersection of the sixth horizontal virtual line HL6 and the fifth vertical virtual line VL5. By repeating this process, the plurality of shielded polysilicon contact holes 14 having a shape as shown in the drawing may be formed.

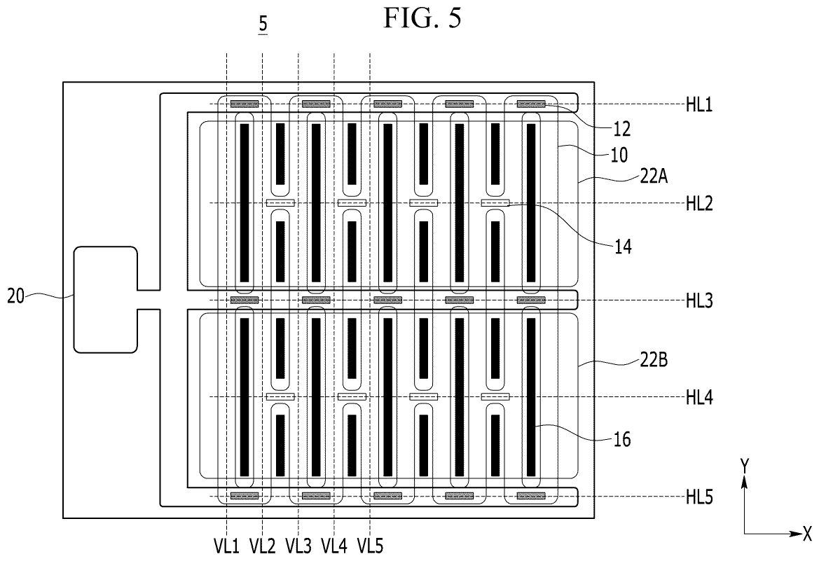

FIG. 5 is a drawing for explaining a semiconductor device according to an embodiment.

Referring to FIG. 5, a semiconductor device 5 according to an embodiment is different from the semiconductor device 2 in that the patterns of the semiconductor device 2 described in relation to FIG. 2 are disposed at the upper portion and the lower portion, and a gate bus which extends along the third horizontal virtual line HL3 between the upper portion and the low portion is additionally formed. In this case, on the gate bus additionally formed, some portions of the plurality of gate polysilicon contact holes 12 may be disposed. As the gate bus which extend along the third horizontal virtual line HL3 is additionally formed as described above, the switching speed may be increased. For example, as compared to the embodiments described in relation to FIGS. 1 to 3, the gate internal resistance is approximately halved, whereby the switching speed is increased. Hereinafter, the difference from the semiconductor device 2 will be mainly described, and in the range where the gate bus is not disposed, the above description related to the semiconductor device 2 may also be applied to the semiconductor device 5.

For clarity of description, on the upper surface of the semiconductor device 5, a plurality of horizontal virtual lines HL1 to HL5 which extends in parallel with one another along the first axial direction may be defined. Further, on the upper surface of the semiconductor device 5, a plurality of vertical virtual lines VL1 to VL5 which extends in parallel with one another along the second axial direction may be defined. It is apparent that besides the numbers of horizontal virtual lines and vertical virtual lines shown in the drawing, horizontal virtual lines and vertical virtual lines may be further defined on the upper surface of the semiconductor device 5 although omitted for visual clarity of the drawing.

The trench region 10 may be formed so as to continuously extend along the plurality of horizontal virtual lines HL1 to HL3 and the plurality of vertical virtual lines VL1 to VL5. Specifically, the trench region 10 may be formed so as to extend along the second axial direction along the first vertical virtual line VL1, extend along the first axial direction from the intersection of the first vertical virtual line VL1 and the first horizontal virtual line HL1 to the intersection of the first horizontal virtual line HL1 and the second vertical virtual line VL2, extend along the first axial direction from the intersection of the first vertical virtual line VL1 and the third horizontal virtual line HL3 to the intersection of the third horizontal virtual line HL3 and the second vertical virtual line VL2, and extend along the first axial direction from the intersection of the first vertical virtual line VL1 and the fifth horizontal virtual line HL5 to the intersection of the fifth horizontal virtual line HL5 and the second vertical virtual line VL2. Subsequently, the trench region 10 may be formed so as to extend along the second axial direction from the intersection of the second vertical virtual line VL2 and the first horizontal virtual line HL1 to the intersection of the fifth horizontal virtual line HL5 and the second vertical virtual line VL2, extend along the first axial direction from the intersection of the second vertical virtual line VL2 and the second horizontal virtual line HL2 to the intersection of the second horizontal virtual line HL2 and the third vertical virtual line VL3, and extend along the first axial direction from the intersection of the second vertical virtual line VL2 and the fourth horizontal virtual line HL4 to the intersection of the fourth horizontal virtual line HL4 and the third vertical virtual line VL3.

Meanwhile, the trench region 10 may extend in the second axial direction along the third vertical virtual line VL3, extend along the first axial direction from the intersection of the third vertical virtual line VL3 and the first horizontal virtual line HL1 to the intersection of the first horizontal virtual line HL1 and the fourth vertical virtual line VL4, extend along the first axial direction from the intersection of the third vertical virtual line VL3 and the third horizontal virtual line HL3 to the intersection of the third horizontal virtual line HL3 and the fourth vertical virtual line VL4, and extend along the first axial direction from the intersection of the third vertical virtual line VL3 and the fifth horizontal virtual line HL5 to the intersection of the fifth horizontal virtual line HL5 and the fourth vertical virtual line VL4. Subsequently, the trench region 10 may be formed so as to extend along the second axial direction from the intersection of the fourth vertical virtual line VL4 and the first horizontal virtual line HL1 to the intersection of the fifth horizontal virtual line HL5 and the fourth vertical virtual line VL4, extend along the first axial direction from the intersection of the fourth vertical virtual line VL4 and the second horizontal virtual line HL2 to the intersection of the second horizontal virtual line HL2 and the fifth vertical virtual line VL5, and extend along the first axial direction from the intersection of the fourth vertical virtual line VL4 and the fourth horizontal virtual line HL4 to the intersection of the fourth horizontal virtual line HL4 to the fifth vertical virtual line VL5. By repeating this process, the trench region 10 having a shape as shown in the drawing may be formed.

Among the plurality of gate polysilicon contact holes 12, a first gate polysilicon contact hole may be formed so as to extend along the first axial direction between the intersection of the first vertical virtual line VL1 and the first horizontal virtual line HL1 and the intersection of the first horizontal virtual line HL1 and the second vertical virtual line VL2. Next, a second gate polysilicon contact hole may be formed so as to extend along the first axial direction between the intersection of the third vertical virtual line VL3 and the first horizontal virtual line HL1 and the intersection of the first horizontal virtual line HL1 and the fourth vertical virtual line VL4. Meanwhile, among the plurality of gate polysilicon contact holes 12, a third gate polysilicon contact hole may be formed so as to extend along the first axial direction between the intersection of the first vertical virtual line VL1 and the third horizontal virtual line HL3 and the intersection of the third horizontal virtual line HL3 and the second vertical virtual line VL2. Next, a fourth gate polysilicon contact hole may be formed so as to extend along the first axial direction between the intersection of the third vertical virtual line VL3 and the third horizontal virtual line HL3 and the intersection of the third horizontal virtual line HL3 and the fourth vertical virtual line VL4. Meanwhile, among the plurality of gate polysilicon contact holes 12, the fifth gate polysilicon contact hole may be formed so as to extend along the first axial direction between the intersection of the first vertical virtual line VL1 and the fifth horizontal virtual line HL5 and the intersection of the fifth horizontal virtual line HL5 and the second vertical virtual line VL2. Next, the sixth gate polysilicon contact hole may be formed so as to extend along the first axial direction between the intersection of the third vertical virtual line VL3 and the fifth horizontal virtual line HL5 and the intersection of the fifth horizontal virtual line HL5 and the fourth vertical virtual line VL4. By repeating this process, the plurality of gate polysilicon contact holes 12 having a shape as shown in the drawing may be formed.

Among the plurality of shielded polysilicon contact holes 14, a first shielded polysilicon contact hole may be formed so as to extend along the first axial direction between the intersection of the second vertical virtual line VL2 and the second horizontal virtual line HL2 and the intersection of the second horizontal virtual line HL2 and the third vertical virtual line VL3. Next, a second shielded polysilicon contact hole may be formed so as to extend along the first axial direction between the intersection of the fourth vertical virtual line VL4 and the second horizontal virtual line HL2 and the intersection of the second horizontal virtual line HL2 and the fifth vertical virtual line VL5. Meanwhile, among the plurality of shielded polysilicon contact holes 14, the third shielded polysilicon contact hole may be formed so as to extend along the first axial direction between the intersection of the second vertical virtual line VL2 and the fourth horizontal virtual line HL4 and the intersection of the fourth horizontal virtual line HL4 and the third vertical virtual line VL3. Next, the fourth shielded polysilicon contact hole may be formed so as to extend along the first axial direction between the intersection of the fourth vertical virtual line VL4 and the fourth horizontal virtual line HL4 and the intersection of the fourth horizontal virtual line HL4 and the fifth vertical virtual line VL5. By repeating this process, the plurality of shielded polysilicon contact holes 14 having a shape as shown in the drawing may be formed.

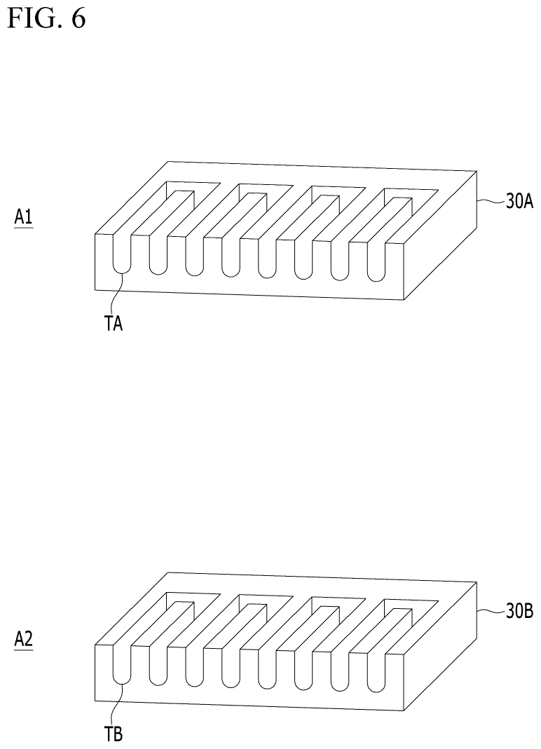

FIGS. 6 to 17 are drawings for explaining a method of manufacturing a semiconductor device according to an embodiment. In each of FIGS. 6 to 17, a structure which is illustrated as “A1” on the top of the drawing may correspond to the structure of the region denoted by “A1” in FIG. 1, and a structure which is illustrated as “A2” on the bottom of the drawing may correspond to the structure of the region denoted by “A2” in FIG. 1.

Referring to FIG. 6, a substrate 30 may be an epitaxial single-crystalline silicon layer which is formed on a semiconductor substrate. The substrate 30 may include a first layer having a first conductivity type, for example, an n type. The substrate 30 may further include a first contact layer formed on the first layer. The first contact layer may have a second conductivity type, for example, a p type doped with p-type impurities. The substrate 30 may further include a second contact layer formed on the first contact layer. The second contact layer may be a layer doped with high-concentration n-type impurity ions, and may be referred to as a source contact layer. As shown in the drawings, in the substrate 30, a trench TA, TB is formed, the first contact layer and the second contact layer which is formed on the first contact layer may be formed between each trench cell belonging to the trench TA, TB and the neighboring trench cells. The trench TA, TB may be formed through various known etching processes.

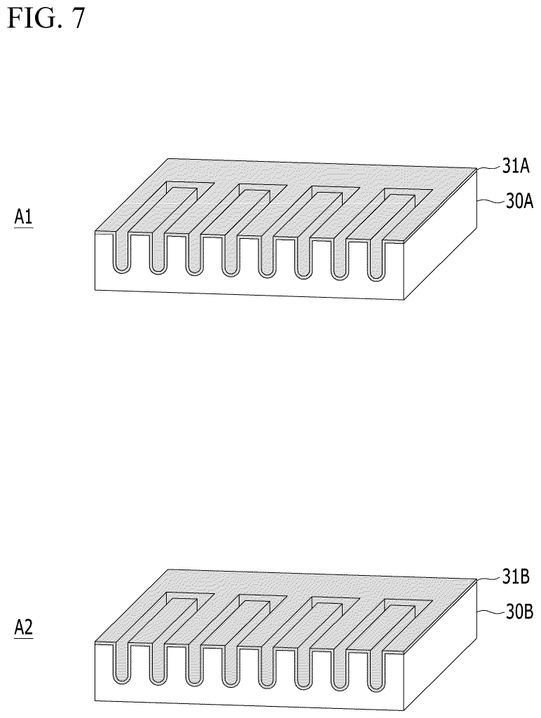

Referring to FIG. 7, on the substrate 30, a shielded oxide layer 31A, 31B may be formed. The shielded oxide layer 31A, 31B may contain, for example, silicon oxide which is formed in various manners such as thermal CVD. The shielded oxide layer 31A, 31B may be formed on the substrate 30 so as to be continuous and conform to the substrate.

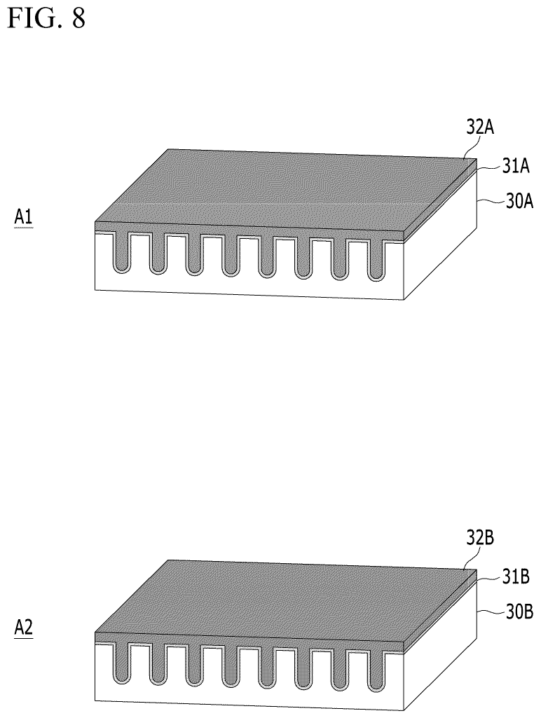

Referring to FIG. 8, on the shielded oxide layer 31A, 31B, a shielded polysilicon layer 32A, 32B may be formed by deposition. As shown in the drawing, the shielded polysilicon layer 32A, 32B may be formed so as to fill the inside of the trench TA, TB and entirely cover the shielded oxide layer 31A, 31B.

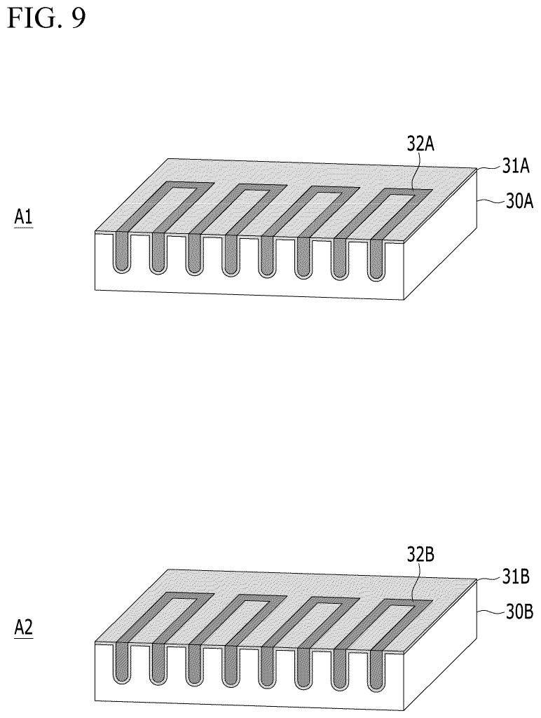

Referring to FIG. 9, at least some portions of the shielded polysilicon layer 32A, 32B may be primarily removed by etching. As shown in the drawing, only the portions of the shielded polysilicon layer 32A, 32B filling the inside of the trench TA, TB may remain and the other portion may be removed such that the upper surface of the shielded oxide layer 31A, 31B is exposed in the region where the trench TA, TB has not been formed.

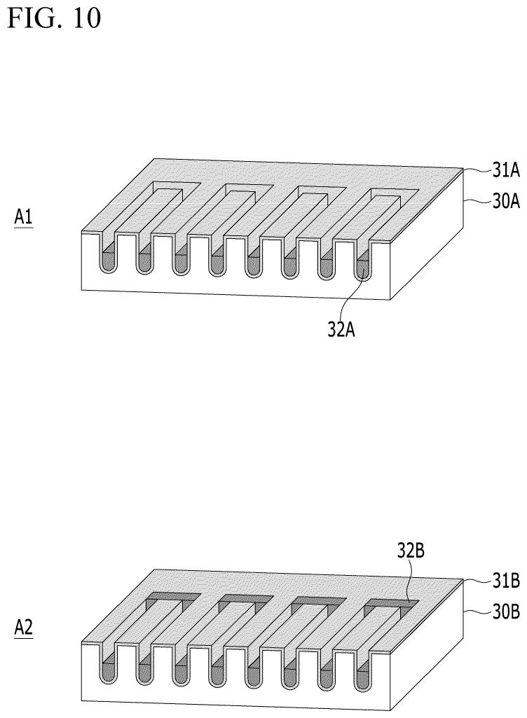

Referring to FIG. 10, at least some portions of the shielded polysilicon layer 32A, 32B may be secondarily removed by etching. At this time, in the case of A1, the secondary etching is performed on the entire shielded polysilicon layer 32A filling in the trench TA, whereas in the case of A2, the portions of the shielded polysilicon layer 32B filling in the trench TB and extending in a transverse direction as seen in the drawing may be processed using a mask, so as not to be etched. Accordingly, the portions of the shielded polysilicon layer 32B filling the trench and extending in the diagonal direction as seen in the drawing may be etched by a target thickness for forming a gate region, and the portions of the shielded polysilicon layer 32B filling the trench and extending in the transverse direction as seen in the drawing may not be removed due to the mask, and their upper surfaces may be exposed along with the shielded oxide layer 31B.

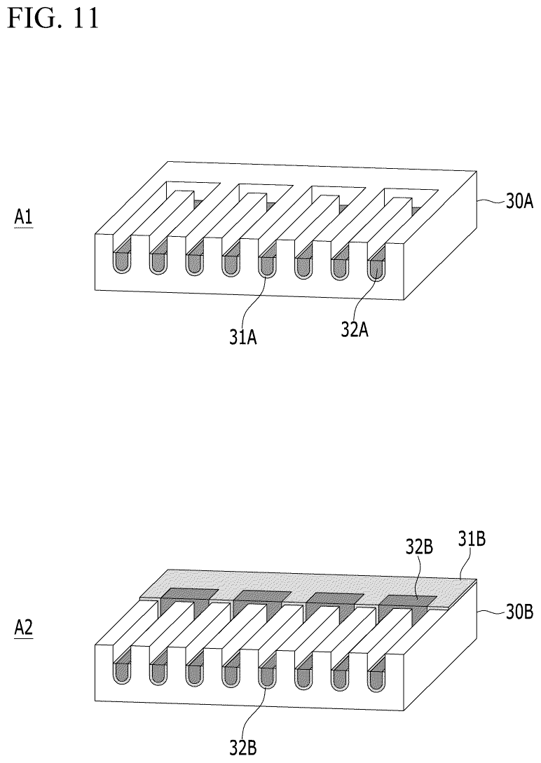

Referring to FIG. 11, at least some portions of the shielded oxide layer 31A, 31B may be removed by etching. At this time, in the case of A1, etching is performed on the entire shielded oxide layer 31A equally to the thickness of the shielded polysilicon layer 32A remaining in the trench TA, whereas in the case of A2, the portion of the shielded oxide layer 31B filling the trench TB and extending in the transverse direction as seen in the drawing may be processed using a mask so as not to be etched. Accordingly, the portions of the shielded oxide layer 31B filling the trench and extending in the diagonal direction as seen in the drawing may be etched equally to the thickness of the shielded polysilicon layer 32B, and the portion of the shielded oxide layer 31B extending in the transverse direction as seen in the drawing may not be removed due to the mask, and its upper surface may be exposed along with the shielded polysilicon layer 32B.

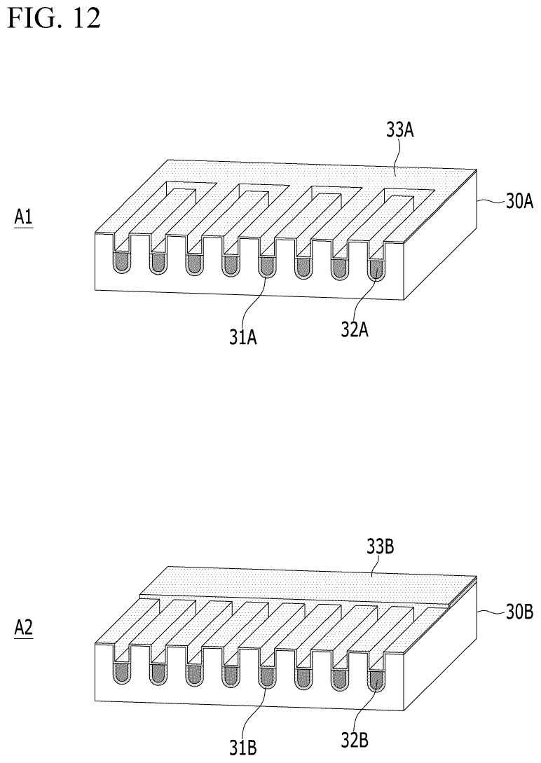

Referring to FIG. 12, a gate oxide layer 33A, 33B may be formed on the substrate 30. The gate oxide layer 33A, 33B may contain silicon oxide which is formed in various manners such as thermal CVD. The gate oxide layer 33A, 33B may be formed on the substrate 30 so as to be continuous and conform to the substrate. In this case, the gate oxide layer 33A, 33B may be formed to be thinner than the shielded oxide layer 31A, 31B.

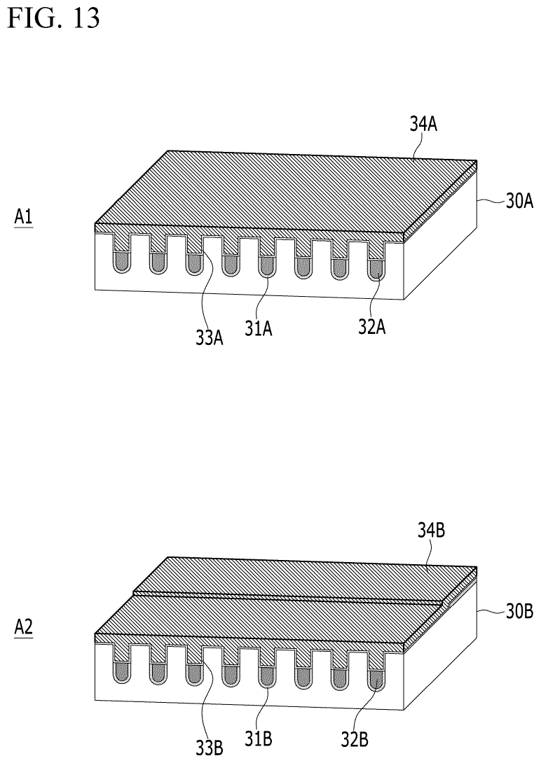

Referring to FIG. 13, on the gate oxide layer 33A, 33B, a gate polysilicon layer 34A, 34B may be formed by deposition. As shown in the drawing, the gate polysilicon layer 34A, 34B may be formed so as to fill the inside of the trench TA, TB and entirely cover the gate oxide layer 33A, 33B.

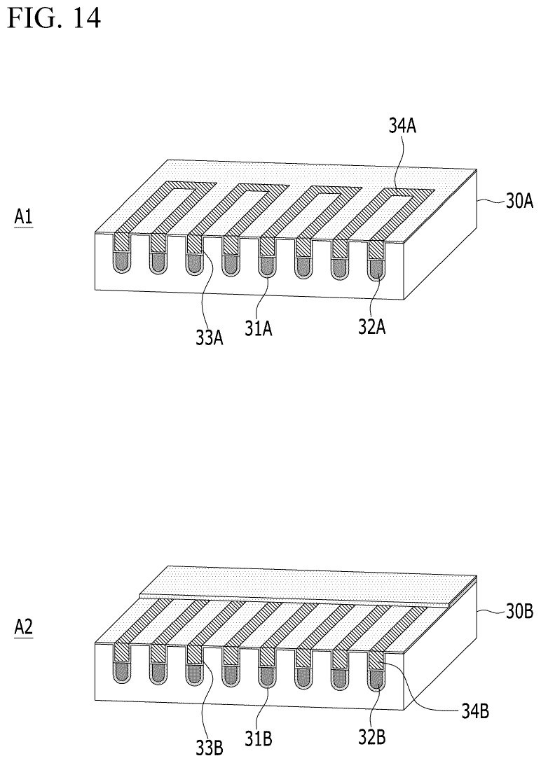

Referring to FIG. 14, at least some portions of the gate polysilicon layer 34A, 34B may be removed by etching. At this time, in the case of A1, etching may be performed on the entire gate polysilicon layer 34A until the upper surface of the gate oxide layer 33A is exposed, whereas in the case of A2, the portion of the gate polysilicon layer 34B extending in the transverse direction as seen in the drawing may be processed using a mask so as not to be etched. Accordingly, the upper surface of the portion of the gate polysilicon layer 34B extending in the diagonal direction as seen in the drawing is etched until the upper surface of the gate oxide layer 33B is exposed, and the portion of the gate polysilicon layer 34B extending in the transverse direction as seen in the drawing is not removed due to the mask.

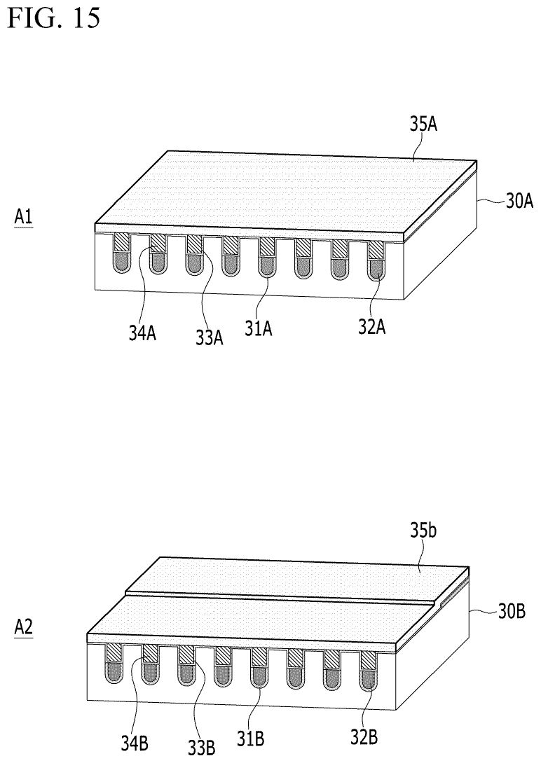

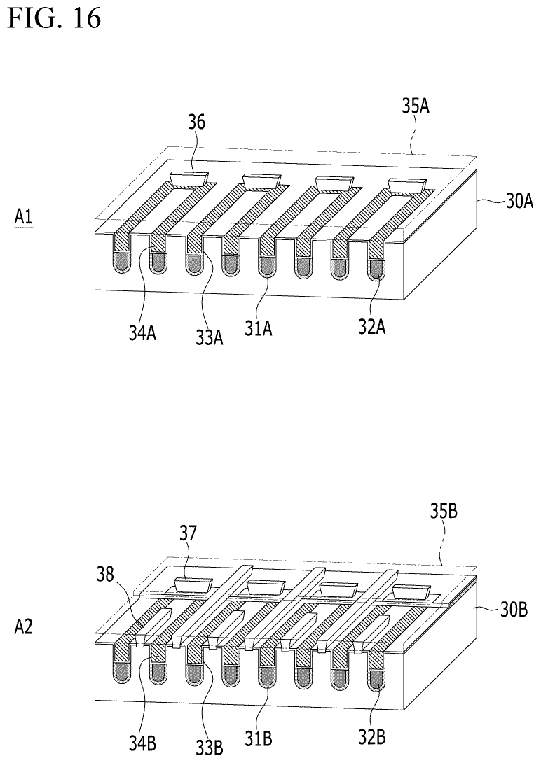

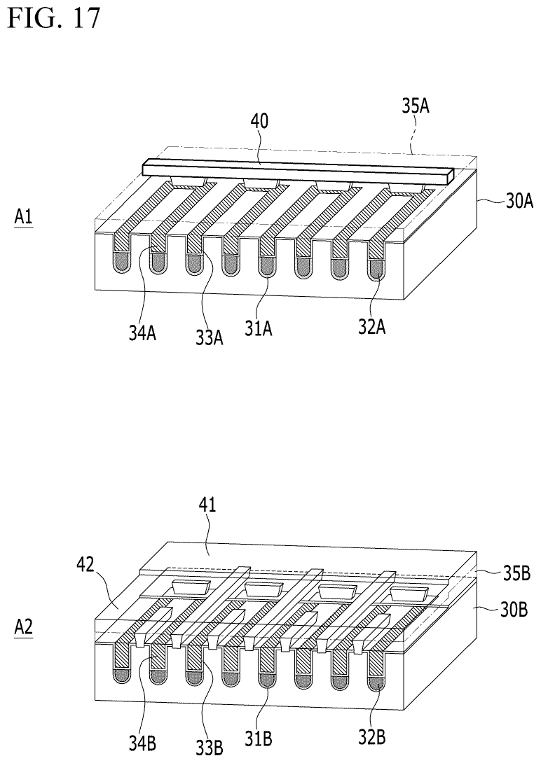

Subsequently, referring to FIG. 15, an interlayer dielectric (ILD) layer 35A, 35B may be formed by deposition, and referring to FIG. 16, gate polysilicon contact holes 36, shielded polysilicon contact holes 37, and source contact holes 38 may be formed so as to be opened, and referring to FIG. 17, gate polysilicon contact metals 40 may be formed so as to pass through the gate polysilicon contact holes 36, and shield polysilicon contact metals 41 may be formed so as to pass through the shielded polysilicon contact holes 37, and source contact metals 42 may be formed so as to pass through the source contact holes 38.

According to the embodiment described above, it is possible to provide a semiconductor device capable of forming electrode contact holes even when trench width is reduced in a trench MOSFET having two or more electrodes in one trench structure to improve the impedance.

Specifically, a region where contacts for the shielded polysilicon layer are formed inside the source contact region can be implemented without the need to further form a region where contacts for the shielded polysilicon layer are formed besides a region where contacts for the gate polysilicon layer are formed. Accordingly, it is possible to maximize the substantial area of an active region. This is because when a region where contacts for the shielded polysilicon layer are formed needs to be further formed in a place other than the gate contact region and the source contact region, in a semiconductor device having the same size, a loss occurs in the area of the active region. As described above, as the ratio of the active region increases, the device characteristics of the semiconductor device can be improved.

Further, by the structures according to the embodiments, the sizes of the plurality of gate polysilicon contact holes and the plurality of shield polysilicon contact holes may be flexibly adjusted. In other words, it is easy to increase the sizes of the plurality of gate polysilicon contact holes and the plurality of shield polysilicon contact holes depending on a specific design purpose or design environment, and even when there is a restriction that the width of the trench region should be designed to be narrow, there is no problem in forming the plurality of gate polysilicon contact holes and the plurality of shield polysilicon contact holes. In other words, there is a great advantage in terms of design flexibility.

In addition, since the direction of the trench where the plurality of gate polysilicon contact holes and the plurality of shield polysilicon contact holes are formed is perpendicular to the direction of the trench of the active region, it is possible to prevent or minimize occurrence of a warpage phenomenon that may occur in thin substrates.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device, wherein:
on the upper surface of the semiconductor device, a first horizontal virtual line, a second horizontal virtual line, a third horizontal virtual line, and a fourth horizontal virtual line which extend in parallel with one another along a first axial direction are defined,
on the upper surface of the semiconductor device, a first vertical virtual line, a second vertical virtual line, and a third vertical virtual line which extend in parallel with one another along a second axial direction perpendicular to the first axial direction are defined,
the semiconductor device includes a trench region, a gate contact region, and a source contact region,
the trench region is formed
so as to extend in the second axial direction along the first vertical virtual line,
extend along the first axial direction from the intersection of the first vertical virtual line and the first horizontal virtual line,
extend along the second axial direction from the intersection of the first horizontal virtual line and the second vertical virtual line, and
extend along the first axial direction from the intersection of the second vertical virtual line and the second horizontal virtual line, and
on the trench region, a plurality of gate polysilicon contact holes and a plurality of shielded polysilicon contact holes are formed.

2. The semiconductor device of claim 1, wherein:
among the plurality of gate polysilicon contact holes, a first gate polysilicon contact hole is formed so as to extend along the first axial direction between the intersection of the first vertical virtual line and the first horizontal virtual line and the intersection of the first horizontal virtual line and the second vertical virtual line.

3. The semiconductor device of claim 2, wherein:
among the plurality of shielded polysilicon contact holes, a first shielded polysilicon contact hole is formed so as to extend along the first axial direction between the intersection of the second vertical virtual line and the second horizontal virtual line and the intersection of the second horizontal virtual line and the third vertical virtual line.

4. The semiconductor device of claim 3, further comprising:
a first source contact hole that is formed so as to extend along the second axial direction between a portion of the trench region extending in the second axial direction along the first vertical virtual line and a portion extending in the second axial direction along the second vertical virtual line; and
a second source contact hole that is formed so as to extend along the second axial direction between a portion of the trench region extending in the second axial direction along the second vertical virtual line and a portion extending in the second axial direction along the third vertical virtual line.

5. The semiconductor device of claim 1, wherein:
the trench region is formed
so as to extend along the first axial direction from the intersection of the first vertical virtual line and the fourth horizontal virtual line,
extend along the second axial direction from the intersection of the fourth horizontal virtual line and the second vertical virtual line, and
extend along the first axial direction from the intersection of the second vertical virtual line and the third horizontal virtual line.

6. The semiconductor device of claim 6, wherein:
among the plurality of gate polysilicon contact holes, a second gate polysilicon contact hole is formed so as to extend along the first axial direction between the intersection of the first vertical virtual line and the fourth horizontal virtual line and the intersection of the fourth horizontal virtual line and the second vertical virtual line.

7. The semiconductor device of claim 6, wherein:
among the plurality of shielded polysilicon contact holes, a second shield polysilicon contact hole is formed so as to extend along the first axial direction between the intersection of the second vertical virtual line and the third horizontal virtual line and the intersection of the third horizontal virtual line and the third vertical virtual line.

8. The semiconductor device of claim 7, further comprising:
a second source contact hole that is formed so as to extend along the second axial direction between a portion of the trench region extending in the second axial direction along the first vertical virtual line and a portion extending in the second axial direction along the second vertical virtual line.

9. The semiconductor device of claim 1, wherein:
the plurality of gate polysilicon contact holes is formed such that the upper surface of a gate polysilicon layer formed inside along the trench region and gate polysilicon contact metals can be in contact.

10. The semiconductor device of claim 9, wherein:
the plurality of shielded polysilicon contact holes is formed such that the upper surface of a shielded polysilicon layer formed inside along the trench region and shield polysilicon contact metals can be in contact.

11. The semiconductor device of claim 1, wherein:
a plurality of gate polysilicon contact holes and a plurality of shielded polysilicon contact holes are formed only along the first axial direction, and are not formed along the second axial direction.

12. A semiconductor device, wherein:
on the upper surface of the semiconductor device, a first horizontal virtual line, a second horizontal virtual line, and a third horizontal virtual line which extend in parallel with one another along a first axial direction are defined,
on the upper surface of the semiconductor device, a first vertical virtual line, a second vertical virtual line, and a third vertical virtual line which extend in parallel with one another along a second axial direction perpendicular to the first axial direction are defined,
the semiconductor device includes a trench region, a gate contact region, and a source contact region,
the trench region is formed
so as to extend in the second axial direction along the first vertical virtual line,
extend along the first axial direction from the intersection of the first vertical virtual line and the first horizontal virtual line,
extend along the first axial direction from the intersection of the first vertical virtual line and the third horizontal virtual line,
extend along the second axial direction from the intersection of the first horizontal virtual line and the second vertical virtual line to the intersection of the third horizontal virtual line and the second vertical virtual line, and
extend along the first axial direction from the intersection of the second vertical virtual line and the second horizontal virtual line, and
on the trench region, a plurality of gate polysilicon contact holes and a plurality of shielded polysilicon contact holes are formed.

13. The semiconductor device of claim 12, wherein:
among the plurality of gate polysilicon contact holes, a first gate polysilicon contact hole is formed so as to extend along the first axial direction between the intersection of the first vertical virtual line and the first horizontal virtual line and the intersection of the first horizontal virtual line and the second vertical virtual line, and
among the plurality of gate polysilicon contact holes, a second gate polysilicon contact hole is formed so as to extend along the first axial direction between the intersection of the first vertical virtual line and the third horizontal virtual line and the intersection of the third horizontal virtual line and the second vertical virtual line.

14. The semiconductor device of claim 13, wherein:
among the plurality of shielded polysilicon contact holes, a first shielded polysilicon contact hole is formed so as to extend along the first axial direction between the intersection of the second vertical virtual line and the second horizontal virtual line and the intersection of the second horizontal virtual line and the third vertical virtual line.

15. The semiconductor device of claim 14, further comprising:
a first source contact hole that is formed so as to extend along the second axial direction between a portion of the trench region extending in the second axial direction along the first vertical virtual line and a portion extending in the second axial direction along the second vertical virtual line; and
a second source contact hole that is formed so as to extend along the second axial direction between a portion of the trench region extending in the second axial direction along the second vertical virtual line and a portion extending in the second axial direction along the third vertical virtual line.

16. The semiconductor device of claim 12, wherein:
among the plurality of gate polysilicon contact holes, a first gate polysilicon contact hole is formed so as to extend along the first axial direction between the intersection of the second vertical virtual line and the second horizontal virtual line and the intersection of the second horizontal virtual line and the third vertical virtual line.

17. The semiconductor device of claim 16, wherein:
among the plurality of shielded polysilicon contact holes, a first shielded polysilicon contact hole is formed so as to extend along the first axial direction between the intersection of the first vertical virtual line and the first horizontal virtual line and the intersection of the first horizontal virtual line and the second vertical virtual line, and
among the plurality of gate polysilicon contact holes, a second gate polysilicon contact hole is formed so as to extend along the first axial direction between the intersection of the first vertical virtual line and the third horizontal virtual line and the intersection of the third horizontal virtual line and the second vertical virtual line.

18. The semiconductor device of claim 17, further comprising:
a first source contact hole that is formed so as to extend along the second axial direction between a portion of the trench region extending in the second axial direction along the first vertical virtual line and a portion extending in the second axial direction along the second vertical virtual line; and
a second source contact hole that is formed so as to extend along the second axial direction between a portion of the trench region extending in the second axial direction along the second vertical virtual line and a portion extending in the second axial direction along the third vertical virtual line.

19. The semiconductor device of claim 17, further comprising:
a gate bus where the plurality of gate polysilicon contact holes is formed along the second horizontal virtual line.

20. The semiconductor device of claim 12, wherein:
a plurality of gate polysilicon contact holes and a plurality of shielded polysilicon contact holes are formed only along the first axial direction, and are not formed along the second axial direction.
